(19) United States
(12) Patent Application Publication
(10) Pub. No.: US 2016/0313818 A1
(43) Pub. Date: Oct. 27, 2016

(54) Apparatus, System and Method of Manufacturing a Touch Panel

(71) Applicant: JUSUNG ENGINEERING CO., LTD., Gwangju-si (KR)

(72) Inventors: Seon Myung KIM, Gwangju-si (KR); Young Gi KIM, Gwangju-si (KR); Kyung In MIN, Gwangju-si (KR); Il Houng PARK, Gwangju-si (KR); Chang Kyun PARK, Gwangju-si (KR)

(73) Assignee: Jusung Engineering Co., Ltd., Gwangju-si (KR)

(21) Appl. No.: 15/104,518

(22) PCT Filed: Dec. 18, 2014
(86) PCT No.: PCT/KR2014/012528

§ 371 Date: Jun. 14, 2016

(30) Foreign Application Priority Data
Dec. 19, 2013 (KR) 10-2013-0158852

(51) Int. Cl. G06F 3/041; C23C 16/44; C23C 16/40

(52) U.S. Cl. CPC G06F 3/041; C23C 16/40; C23C 16/44; G06F 2203/04103

(57) ABSTRACT

Disclosed are an apparatus, system, and method for manufacturing a touch panel, which form a bridge with transparent first oxide having conductivity and forms second oxide, which is robust to a high temperature and high humidity, on the bridge. The method includes forming a plurality of electrode parts in a display area of a substrate, forming a light blocking layer in a non-display area of the substrate, forming an electrode line on the light blocking layer, forming a line bridge by using transparent first oxide having conductivity, and forming second oxide on the first oxide for protecting the first oxide.

### TECHNICAL FIELD

The present invention relates to a method of manufacturing a touch panel, and particularly, to an apparatus, system, and method for manufacturing a touch panel attached to a surface of a panel configuring a display device.

### BACKGROUND ART

A flat panel display (FPD) device is applied to various electronic devices such as portable phones, tablet personal computers (PCs), notebook computers, etc. Examples of the FPD device include liquid crystal display (LCD) devices, plasma display panels (PDPs), organic light emitting display devices, etc. Recently, electrophoretic display (EPD) devices are being widely used as one type of the FPD device.

In such FPD devices (hereinafter simply referred to as a display device), the LCD devices are being the most widely commercialized at present because the LCD devices are easily manufactured due to the advance of manufacturing technology and realize a drivability of a driver and a high-quality image.

In such FPD devices, the organic light emitting display devices have a fast response time of 1 ms or less and low power consumption, and thus are attracting much attention as next generation FPD devices.

Instead of a mouse or a keyboard which is conventionally applied to flat panel display devices, a touch screen that enables a user to directly input information with a finger or a pen is recently applied to the flat panel display devices.

Examples of a type, in which the touch panel is applied to a panel of an LCD device displaying an image, include an add-on type and an in-cell type.

An add-on type touch panel is manufactured independently from the panel, and is adhered to a plane of the panel. Also, the in-cell type touch panel is provided as one body with the panel.

FIG. 1 is an exemplary diagram schematically illustrating a cross-sectional surface of a related art add-on type touch panel, and particularly is an exemplary diagram schematically illustrating a light blocking layer, which is formed in a non-display area of the touch panel, and a line which is formed at the light blocking layer.

The add-on type touch panel, as described above, is attached to a panel which displays an image in a display device.

First, an X-axis electrode sensor pattern (hereinafter simply referred to as a driving electrode) and a Y-axis electrode sensor pattern (hereinafter simply referred to as a receiving electrode) are formed of indium oxide tin (ITO, a transparent electrode) in a display area M of the touch panel. ITO forming the touch panel may be applied to a glass substrate or a film (hereinafter simply referred to as a substrate 11).

In the touch panel, the driving electrode is separated from the receiving electrode by an insulator so that the driving electrode is electrically disconnected from the receiving electrode. In this case, a line passing through an upper surface or a lower surface of the insulator is referred to as an electrode bridge. The electrode bridge electrically connects a plurality of driving electrode parts which are separated from each other, or electrically connects a plurality of receiving electrode parts which are separated from each other.

Second, as illustrated in FIG. 1, a driving electrode line connected to the driving electrode or a receiving electrode line connected to the receiving electrode is formed in a non-display area N of the touch panel. Hereinafter, a case in which a line 14 illustrated in FIG. 1 is the receiving electrode line will be described as an example of a related art touch panel.

A light blocking layer 12 is formed in the non-display area N so as to prevent light from being leaked, and the receiving electrode line 14 is formed at the light blocking layer 12.

In this case, a line for electrically connecting the receiving electrode 13 (which is formed in the display area M) to the receiving electrode line 14 formed in the non-display area N is referred to as a receiving line bridge 15. Also, a line for electrically connecting the driving electrode (which is formed in the display area M) to the driving electrode line formed in the non-display area N is referred to as a driving line bridge 15.

A generic name for a driving electrode bridge that electrically connects a plurality of driving electrode parts configuring the driving electrode formed in the display area M, a receiving electrode bridge that electrically connects a plurality of receiving electrode parts configuring the receiving electrode formed in the display area M, the driving line bridge that connects the driving electrode, formed in the display area M, to the driving electrode line formed in the non-display area N, and the receiving line bridge 15 that connects the receiving electrode, formed in the display area M, to the receiving electrode line formed in the non-display area N is a bridge.

Generally, the electrode bridge and the line bridge are simultaneously formed on the substrate 11 through the same process.

The related art touch panel having the above-described structure has the following problems.

Generally, ITO which is formed on a substrate by a physical vapor deposition (PVD) process is not good in step coverage, and a thickness of each of the electrode bridge, the driving electrode, and the receiving electrode 13 which are formed of ITO is 300 nm. A thickness B of the light blocking layer 12 is 20 μm or more which is 70 times thicker than a thickness of the electrode bridge.

Therefore, when the line bridge 15 is formed of ITO for forming the related art touch panel, the line bridge 15 is not electrically connected to the electrode line 14 formed on the light blocking layer 12.

To provide an additional description, when ITO is sputtered by the PVD process so as to form the line bridge 15, as illustrated in FIG. 1, the line bridge 15 is formed to climb a side of the light blocking layer 12, and for this reason, it is difficult to stably implement the line bridge 15. Therefore, a disconnection region C occurs in the line bridge 15 which is formed along the side of the light blocking layer 12.

In particular, due to a step height between the light blocking layer 12 and the substrate 11, a precision of an exposure process using a mask is reduced, and for this reason, there is a high possibility that disconnection occurs in the line bridge 15.

Moreover, since an etching solution reacts with the light blocking layer 12 in an etching process using ITO for forming the line bridge 15, a quality of the line bridge 15 is degraded. Also, in a high-temperature sputtering process using ITO, a gas which is produced on a surface of the light blocking layer 12 can obstruct forming of the line bridge 15, and for this reason, it is difficult to implement the line bridge 15 having uniform quality. Also, the light blocking layer 12 can be oxidized in the high-temperature sputtering process, causing the degradation in a quality of the line bridge 15 formed of ITO.

For this reason, an error rate of the related art touch panel increases, and thus, the manufacturing cost of the touch panel increases.

In particular, a thickness of the light blocking layer 12 which is formed in a touch panel applied to cellular phones using a white bezel is 60 μm or more, and for this reason, a productivity of the touch panel is mere about 20%.

### DISCLOSURE

### Technical Problem

Accordingly, the present invention is directed to provide an apparatus, system, and method for manufacturing a touch panel that substantially obviate one or more problems due to limitations and disadvantages of the related art.

An aspect of the present invention is directed to provide an apparatus, system, and method for manufacturing a touch panel, which form a bridge with transparent first oxide having conductivity and forms second oxide, which is robust to a high temperature and high humidity, on the bridge.

### Technical Solution

To achieve these and other advantages and in accordance with the purpose of the invention, as embodied and broadly described herein, there is provided a method of manufacturing a touch panel including: forming a plurality of electrode parts in a display area of a substrate; forming a light blocking layer in a non-display area of the substrate; forming an electrode line on the light blocking layer; forming a first oxide layer by using first oxide, for forming a line bridge which connects the electrode part to the electrode line; and forming a second oxide layer on the first oxide layer by using second oxide which has a lower step coverage than a step coverage of the first oxide and has a lower resistance than a resistance of the first oxide, for protecting the first oxide.

In another aspect of the present invention, there is provided a touch panel manufacturing apparatus including: a chamber that includes a reaction space; a susceptor that is disposed in the chamber, is supplied with power having a first polarity, and supports a manufacturing substrate which includes a plurality of electrode parts which are formed in a display area, a light blocking layer formed in a non-display area which is formed outside the display area, an electrode line formed on the light blocking layer, and a line bridge which is formed of first oxide by a metal organic chemical vapor deposition (MOCVD) process and connects the electrode part to the electrode line; and a target supporting part that is equipped with a second oxide target, and is supplied with power having a second polarity, wherein the touch panel manufacturing apparatus collides ions of discharged inert gases with the second oxide target and deposits atoms, separated from the second oxide target, on the first oxide to form second oxide on the first oxide.

In another aspect of the present invention, there is provided a touch panel manufacturing system including: a first touch panel manufacturing apparatus that jets a metal source material and a reaction gas onto a manufacturing substrate for forming first oxide, which is used as a line bridge connecting an electrode part to an electrode line, on the manufacturing substrate, wherein the manufacturing substrate includes the plurality of electrode parts formed in a display area, a light blocking layer formed in a non-display area which is formed outside the display area, and the electrode line formed on the light blocking layer; and a second touch panel manufacturing apparatus that forms second oxide, which is more robust than the first oxide to a high temperature and high humidity, on the first oxide of the manufacturing substrate unloaded from the first touch panel manufacturing apparatus.

In another aspect of the present invention, there is provided a method of manufacturing a touch panel including: forming a plurality of electrode parts in a display area of a substrate; forming a light blocking layer in a non-display area of the substrate; forming an electrode line on the light blocking layer; forming a step coverage increase layer for forming a line bridge which connects the electrode part to the electrode line; and forming a resistance decrease layer on the step coverage increase layer.

It is to be understood that both the foregoing general description and the following detailed description of the present invention are exemplary and explanatory and are intended to provide further explanation of the invention as claimed.

### Advantageous Effect

According to the embodiments of the present invention, since a bridge is formed of transparent first oxide having conductivity, a step coverage of the bridge can be improved, and the manufacturing cost of a touch panel can be reduced.

Moreover, according to the embodiments of the present invention, since second oxide for protecting the first oxide from a high temperature and high humidity is formed on the transparent first oxide having conductivity, a characteristic of the first oxide can be improved.

### DESCRIPTION OF DRAWINGS

FIG. 1 is an exemplary diagram schematically illustrating a cross-sectional surface of a related art add-on type touch panel;

FIG. 2 is an exemplary diagram schematically illustrating a touch panel manufactured by a touch panel manufacturing method according to an embodiment of the present invention;

FIG. 3 is an exemplary embodiment illustrating in detail the touch panel of FIG. 2;

FIG. 4 is an exemplary diagram illustrating a cross-sectional surface taken along line X-X′ in the touch panel of FIG. 3;

FIG. 5 is a graph showing characteristics of oxides applied to a touch panel manufacturing method according to an embodiment of the present invention;

FIGS. 6A to 6G are exemplary diagrams sequentially illustrating a touch panel manufacturing method according to an embodiment of the present invention;

FIG. 7 is an exemplary diagram illustrating a configuration of a touch pane manufacturing system according to an embodiment of the present invention;

FIG. 8 is an exemplary diagram illustrating a first touch panel manufacturing apparatus of FIG. 7; and

FIG. 9 is an exemplary diagram illustrating a second touch panel manufacturing apparatus of FIG. 7.

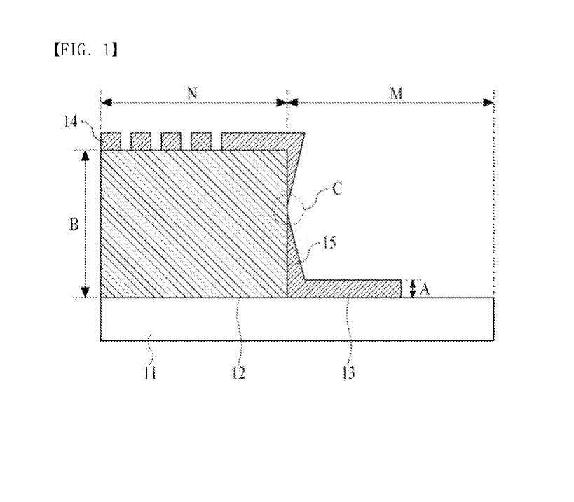

### MODE FOR INVENTION

Reference will now be made in detail to the exemplary embodiments of the present invention, examples of which are illustrated in the accompanying drawings. Wherever possible, the same reference numbers will be used throughout the drawings to refer to the same or like parts.

Hereinafter, embodiments of the present invention will be described in detail with reference to the accompanying drawings.

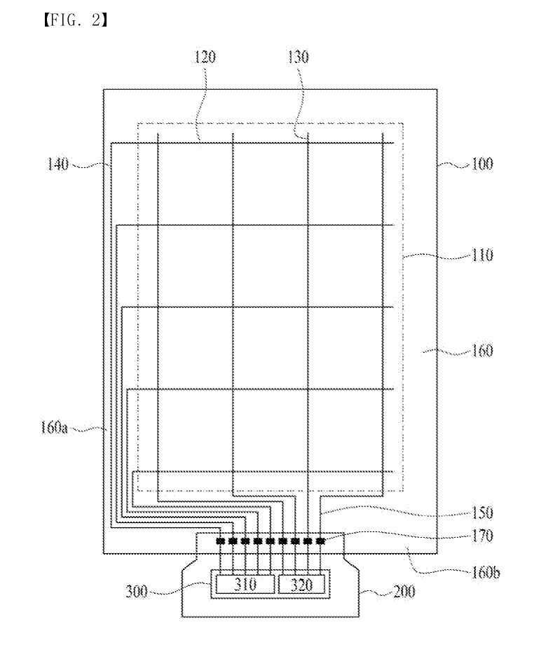

FIG. 2 is an exemplary diagram schematically illustrating a touch panel manufactured by a touch panel manufacturing method according to an embodiment of the present invention.

Examples of a touch panel driving method include a resistive type and a capacitance type. The capacitance type may be categorized into a self-capacitance type and a mutual type. The present invention may be applied to a self-capacitive touch panel and a mutual touch panel. Hereinafter, for convenience of a description, the mutual touch panel will be described as an example of the present invention. Here, the mutual touch panel includes a plurality of driving electrodes and a plurality of receiving electrodes, and determines whether there is a touch, by using a plurality of sensing signals which are received from the receiving electrodes according to a driving pulse sequentially supplied to the driving electrodes.

Moreover, examples of a method in which the touch panel is applied to a panel displaying an image in various types of display devices such as LCD devices, OLED display devices, PDPs, and EPD devices include an add-on type, an in-cell type, a hybrid in-cell type, and an on-cell type. The present invention may be applied to various types of touch panels. Hereinafter, for convenience of a description, a touch panel manufacturing method according to an embodiment of the present invention will be described with an add-on type touch panel as an example. Here, the add-on type touch panel denotes a touch panel that is manufactured independently from the panel and then is attached to a surface of the panel.

A touch panel 100 of FIG. 2, which is manufactured by a touch panel manufacturing method according to an embodiment of the present invention, is manufactured in the add-on type by using the mutual type and determines whether there is a user's touch.

The touch panel 100 includes a display area 110, which corresponds to an area displaying an image in the panel, and a non-display area 160 corresponding to an area which cannot display an image in the panel.

A plurality of driving electrodes 130 and a plurality of receiving electrodes 120 for sensing a touch are formed in the display area 110, and light output from the panel passes through the display area 110.

The non-display area 160 is an area which is covered by a case of a display device, and is referred to as a bezel. As described above, an image is not displayed in the non-display area 160, and light should not be leaked to the non-display area 160. A light blocking layer is formed in the non-display area 160, for preventing light from being leaked.

For example, the add-on type touch panel 100 may be provided on a transparent glass substrate and then may be coupled to the panel, and thus may transmit light which is output through the panel. However, the light output through the panel should not pass through the non-display area 160, and thus, the light blocking layer is formed in the non-display area 160 and blocks light.

In the display area 110 of the touch panel 100, a plurality of receiving electrodes (RX) 120 are formed in one direction (for example, a horizontal direction of FIG. 2), and a plurality of driving electrodes (TX) 130 are formed in the other direction (for example, a vertical direction of FIG. 2). Hereinafter, for convenience of a description, a touch panel in which five receiving electrodes 120 and four driving electrodes 130 are formed will be described as an example of the present invention. However, the number of the receiving electrodes 120 and the number of the driving electrodes 130 may be variously changed depending on a size of the touch panel.

Five receiving electrode lines 140 respectively connected to the five receiving electrodes 120 are formed in a first non-display area 160a of the non-display area 160, for example, a non-display area which is formed on the left of the touch panel 100 illustrated in FIG. 2. Four driving electrode lines 150 respectively connected to the four driving electrodes 130 are formed in a second non-display area 160b of the non-display area 160, for example, a non-display area which is formed at a lower side of the touch panel 100 illustrated in FIG. 2. The five receiving electrode lines 140 extend to the second non-display area 160b.

A pad 170, which is electrically connected to a flexible printed circuit board (FPCB) 200 equipped with a touch driver integrated circuit (IC) 300, is provided at each of ends of the five receiving electrode lines 140 and the four driving electrode lines 150 which are formed in the second non-display area 160b.

For example, when the touch panel 100 is manufactured, a plurality of the pads 170 provided in the second non-display area 160b are electrically connected to the FPCB 200, and the touch panel 100 is coupled to the panel.

The touch driver IC 300 includes a receiving unit 310 and a driving unit 320. The driving unit 320 sequentially supplies a driving pulse to the driving electrodes 130. The receiving unit 310 determines whether the touch panel 100 is touched, by using a plurality of sensing signals which are generated according to the driving pulse and are received from the receiving electrodes 120. A detailed configuration of the touch panel 100 will be described in detail with reference to FIG. 3.

The above-described terms and terms to be described below are defined as follows.

First, a generic name for the driving electrodes 130 and the receiving electrodes 120 is a touch electrode. Therefore, the touch electrode may be the driving electrode or the receiving electrode.

Second, when it is required to distinguish the receiving electrode and the driving electrode, the receiving electrode and the driving electrode may be defined as a first touch electrode and a second touch electrode. In this case, the first touch electrode may be the receiving electrode, and the second touch electrode may be the driving electrode. Alternatively, the first touch electrode may be the driving electrode, and the second touch electrode may be the receiving electrode. Hereinafter, for convenience of a description, a case in which the receiving electrode 120 is the first touch electrode and the driving electrode 130 is the second touch electrode will be described as an example of the present invention.

Third, a generic name for the receiving electrode line 140 and the driving electrode line 150 is an electrode line. Therefore, the electrode line may be the receiving electrode line 140 or the driving electrode line 150.

Fourth, a plurality of receiving electrode parts 121 (see FIG. 3) configuring the receiving electrode 120 which is the first touch electrode are referred to as a plurality of first electrode parts, and a plurality of driving electrode parts 131 (see FIG. 3) configuring the driving electrode 130 which is the second touch electrode are referred to as a plurality of second electrode parts. Also, a line 122 (see FIG. 3) which connects the first electrode parts is referred to as a receiving electrode bridge, and a line 132 (see FIG. 3) which connects the second electrode parts is referred to as a driving electrode bridge.

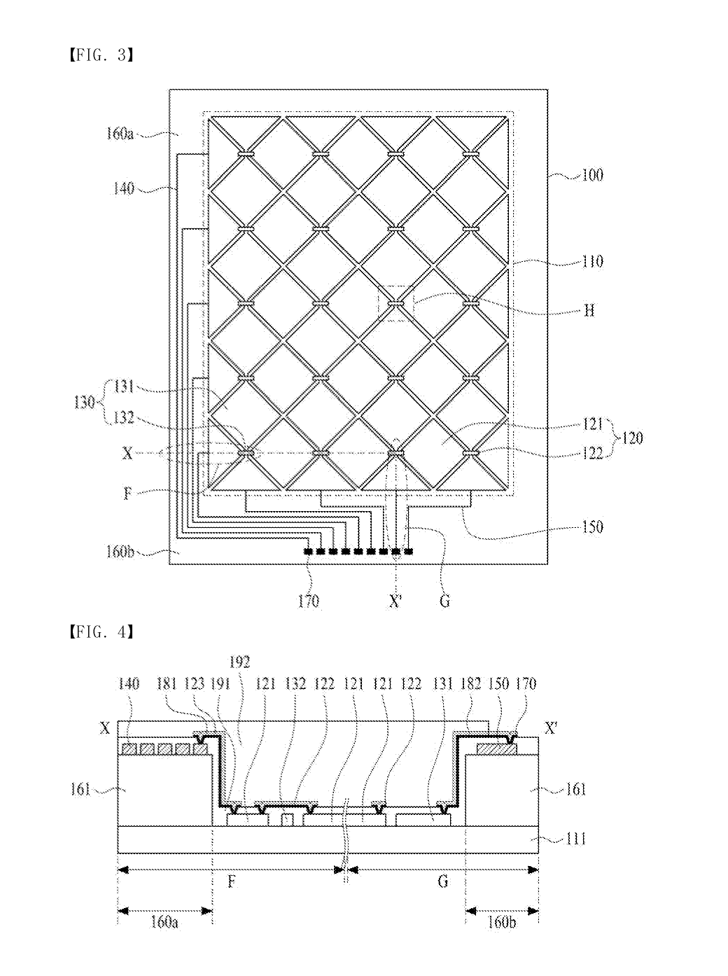

Fifth, the bridge denotes at least one selected from the line bridge and the electrode bridge. The line bridge denotes at least one selected from a receiving line bridge 181 (see FIG. 4) and a driving line bridge 182 (see FIG. 4). In the touch panel illustrated in FIG. 3, the electrode bridge denotes the receiving electrode bridge 122 (see FIG. 3), but in a touch panel having another structure, the electrode bridge may be the driving electrode connection part that connects the driving electrode parts.

Sixth, the electrode line denotes the receiving electrode line or the driving electrode line, and when the receiving electrode line 140 is a first electrode line, the driving electrode line 150 is a second electrode line.

Seventh, first oxide is zinc oxide (ZnO) or boron zinc oxide (BZO) in which boron is doped on ZnO, and a thin layer formed of the first oxide is referred to as a first oxide layer or a step coverage increase layer. The first oxide has a better step coverage than that of second oxide, and thus may be referred to as a step coverage increase layer. In the following description, the first oxide layer and the first oxide are selectively used. That is, the first oxide may denote a material itself, or denote a thin layer formed on the substrate 111.

Eighth, the second oxide may be indium tin oxide (ITO), oxide containing indium, or oxide containing tin. In addition, the second oxide may be one of various materials. The second oxide is a material which has a lower step coverage than that of the first oxide and has a lower resistance than that of the first oxide. Therefore, a thin layer formed of the second oxide is referred to as a second oxide layer or a low resistance layer. In the following description, the second oxide layer and the second oxide are selectively used. That is, the second oxide may denote a material itself, or denote a thin layer formed on the substrate 111.

FIG. 3 is an exemplary embodiment illustrating in detail the touch panel of FIG. 2, and FIG. 4 is an exemplary diagram illustrating a cross-sectional surface taken along line X-X′ in the touch panel of FIG. 3. F of FIG. 4 refers to an F area illustrated in FIG. 3, and G of FIG. 4 refers to a G area illustrated in FIG. 3. FIG. 5 is a graph showing characteristics of oxides applied to a touch panel manufacturing method according to an embodiment of the present invention. FIG. 5 (a) shows a characteristic graph of ITO used as the second oxide, and FIG. 5 (b) shows a characteristic graph of BZO used as the first oxide.

As described above with reference to FIG. 3, the five receiving electrodes 120 and the four driving electrodes 130 are formed in the display area 110 of the touch panel 100, and the receiving electrode lines 140 are formed in the first non-display area 160a. Also, the driving electrode lines 150, the receiving electrode lines 140, and the pads 170 are provided in the second non-display area 160b.

First, the receiving electrodes 120 and the driving electrodes 130 which are formed in the display area 110 will now be described.

The receiving electrode 120 which is formed in a horizontal direction of the touch panel 100 may not electrically be connected to the driving electrode 130 which is formed in a vertical direction of the touch panel 100.

Therefore, the driving electrode 130 and the receiving electrode 120 are separated from each other by an insulator. In this case, in an area where the receiving electrode 120 intersects the driving electrode 130, an electrode bridge is provided in at least one selected from the receiving electrode 120 and the driving electrode 130 in order for the receiving electrode 120 not to be electrically connected to the driving electrode 130.

The electrode bridge may be provided in the receiving electrode 120, and is referred to as a receiving electrode bridge. Also, the electrode bridge may be provided in the driving electrode 130, and is referred to as a driving electrode bridge.

Hereinafter, for convenience of a description, as illustrated in FIGS. 3 and 4, a touch panel in which a receiving electrode bridge 122 is provided in the receiving electrode 120 will be described as an example of the present invention.

When the receiving electrode bridge 122 is provided in the receiving electrode 120, as illustrated in FIG. 3, each of a plurality of the receiving electrodes 120 includes five receiving electrode parts 121 and four receiving electrode bridges 122. One the receiving electrode 120 may be configured with the five receiving electrode parts 121, which are electrically connected by the four receiving electrode bridge 122.

Each of the driving electrodes 130 includes six driving electrode parts 131 and five driving electrode connection parts 132 which electrically connect the driving electrode parts 131 in the intersection area.

Here, as illustrated in FIG. 4, the receiving electrode parts 121, the driving electrode parts 131, and the driving electrode connection parts 132 are disposed on the same layer, and the receiving electrode bridge 122 is separated from the receiving electrode parts 121, the driving electrode parts 131, and the driving electrode connection parts 132 with an insulating layer 191 therebetween.

The receiving electrode parts 121, the driving electrode parts 131, and the driving electrode connection parts 132 may be formed of ITO, oxide containing indium, or oxide containing tin.

Moreover, the receiving electrode parts 121, the driving electrode parts 131, and the driving electrode connection parts 132 may be formed of Zn-based oxide such as ZnO or BZO in which boron is doped on ZnO. Hereinafter, Zn-based oxide such as ZnO or BZO is simply referred to as first oxide. The first oxide is a transparent material having conductivity.

When the receiving electrode parts 121, the driving electrode parts 131, and the driving electrode connection parts 132 are formed of the first oxide having conductivity, the receiving electrode parts 121, the driving electrode parts 131, and the driving electrode connection parts 132 may be formed by depositing ZnO or BZO in a metal organic chemical vapor deposition (MOCVD) process.

When the receiving electrode parts 121, the driving electrode parts 131, and the driving electrode connection parts 132 are formed of the first oxide, the second oxide which is more robust than the first oxide to a high temperature and high humidity may be formed on the first oxide. The second oxide may be formed on the first oxide by a physical vapor deposition (PVD) process.

The electrode bridge 122 is formed of Zn-based oxide such as ZnO or BZO. That is, the electrode bridge 122 is formed of the first oxide having conductivity. Hereinafter, for convenience of a description, a case in which the first oxide is ZnO will be described as an example of the present invention.

Second, the receiving electrode lines 140, the driving electrode lines 150, and the pads 170 which are provided in the first non-display area 160a and the second non-display area 160b will now be described.

As described above with reference to FIG. 4, a light blocking layer 161 for blocking transmission of light is coated in the first non-display area 160a and the second non-display area 160b. A thickness of the light blocking layer 161 is about 20 μm or more. When a thickness of each of the receiving electrode parts 121, the driving electrode parts 131, and the driving electrode connection parts 132 is 300 nm, the light blocking layer 161 is formed about 70 times thicker than the receiving electrode part 121.

The receiving electrode lines 140 connected to the receiving electrodes 120 are disposed on the light blocking layer 161 which is formed in the first non-display area 160a, and the driving electrode line 150 connected to the driving electrode 120 and the pad 170 connected to the driving electrode line 150 are disposed on the light blocking layer 161 which is formed in the second non-display area 160b.

Here, the receiving electrode line 140 is electrically connected to the receiving electrode part 121, which configures the receiving electrode 120 corresponding to the receiving electrode line 140, through a receiving line bridge 181.

For example, a protective layer 192 is coated on the receiving electrode line 140 and the receiving electrode part 121, and contact holes are respectively formed in the receiving electrode line 140 and the protective layer 192 corresponding to the receiving electrode part 121. The receiving line bridge 181 may be electrically connected to the receiving electrode line 140 and the receiving electrode part 121 through the contact hole, and thus, the receiving electrode line 140 may be electrically connected to the receiving electrode part 121.

The driving electrode line 150 is electrically connected to the driving electrode part 131, which configures the driving electrode 130 corresponding to the driving electrode line 150, through a driving line bridge 182. For example, the protective layer 192 is coated on the driving electrode line 150 and the driving electrode part 131, and contact holes are respectively formed in the driving electrode line 150 and the protective layer 192 corresponding to the driving electrode part 131. The driving line bridge 182 may be electrically connected to the driving electrode line 150 and the driving electrode part 131 through the contact hole, and thus, the driving electrode line 150 may be electrically connected to the driving electrode part 131.

The pad 170 may be provided at an end of the driving line bridge 182.

A generic name for the receiving line bridge 181 and the driving line bridge 182 is a line bridge 181 (182). In the following description, the line bridge may denote the receiving line bridge 181 or the driving line bridge 182. In this case, when the receiving line bridge 181 is a first line bridge, the driving line bridge may be a second line bridge, and vice versa.

The line bridges 181 and 182, as illustrated in FIG. 4, are disposed on the same layer as that of the electrode bridge 122.

Therefore, similarly to the electrode bridge 122, the line bridges 181 and 182 are formed by spraying hydrogen onto the ZnO layer (the first oxide) deposited by the MOCVD process, and the second oxide is coated on the ZnO layer. In this case, the second oxide may use a material which is more robust than the first oxide to a high temperature and high humidity.

For example, ITO may be used as the second oxide. In this case, ITO may be formed by the PVD process. Also, Al₂O₃ may be used as the second oxide. Also, the second oxide may be one of various materials for protecting the first oxide.

The reason that a material which is more robust than the first oxide to a high temperature and high humidity is used as the second oxide will be described with reference to FIG. 5.

For example, the graphs shown in FIG. 5 respectively show resistance changes of BZO and ITO which have been measured by changing, to a high temperature and high humidity, an ambient environment of BZO used as the first oxide and an ambient environment of ITO used as the second oxide.

Referring to the graphs, a resistance of ITO is not changed even when a temperature and humidity around ITO increase.

However, when BZO is exposed to a temperature of 85 r and a humidity of 85% RH, a resistance of BZO increases rapidly.

That is, Zn-based oxide, which is used as the first oxide, such as BZO or ZnO having resistance characteristic similar to BZO, may be deposited by the MOCVD process, and has good resistance characteristic at a normal temperature. Therefore, as described above, Zn-based oxide may be used as the receiving line bridge 181, the driving line bridge 182, and the receiving electrode bridge 122, and may be used as the receiving electrode parts 121, the driving electrode parts 131, and the driving electrode connection parts 132.

However, as shown in FIG. 5 (b), BZO and ZnO used as the first oxide are formed on the touch panel, and then, when a temperature and a humidity of the touch panel increase, a resistance of the first oxide increases rapidly. For this reason, functions of the receiving electrode bridge 122, the receiving line bridge 181, the driving line bridge 182, the receiving electrode parts 121, the driving electrode parts 131, and the driving electrode connection parts 132 which are formed of the first oxide can be degraded.

Therefore, according to the present embodiment, the receiving electrode bridge 122, the receiving line bridge 181, the driving line bridge 182, the receiving electrode parts 121, the driving electrode parts 131, and the driving electrode connection parts 132 are formed by using Zn-based oxide, such as BZO or ZnO, as the first oxide, and the second oxide such as ITO or Al₂O₃ is formed on the first oxide, thereby protecting the first oxide. That is, a resistance of the second oxide is not changed even when a temperature and humidity increase, and particularly, the second oxide has a lower resistance than that of the first oxide. Therefore, a second oxide layer formed of the second oxide is referred to as a low resistance layer.

To provide an additional description, the receiving line bridge 181, the driving line bridge 182, and the receiving electrode bridge 122 are formed of the first oxide, which has a good step coverage and conductivity and is transparent, in the MOCVD process, and the second oxide which is robust to a high temperature and high humidity is formed on the first oxide so as to remedy a drawback of the first oxide which is vulnerable to a high temperature and high humidity. Here, the receiving line bridge 181, the driving line bridge 182, or the receiving electrode bridge 122 formed of the first oxide has a good step coverage as described above, and thus is referred to as a step coverage increase layer.

Moreover, in addition to the receiving line bridge 181, the driving line bridge 182, and the receiving electrode bridge 122, the receiving electrode parts 121, the driving electrode parts 131, and the driving electrode connection parts 132 may be formed of the first oxide. In this case, the second oxide may also be formed on the receiving electrode parts 121, the driving electrode parts 131, and the driving electrode connection parts 132.

Here, BZO or ZnO may be used as the first oxide, and the first oxide is formed by the MOCVD process. Also, ITO or Al₂O₃ may be used as the second oxide, and the second oxide is formed on the first oxide by the PVD process.

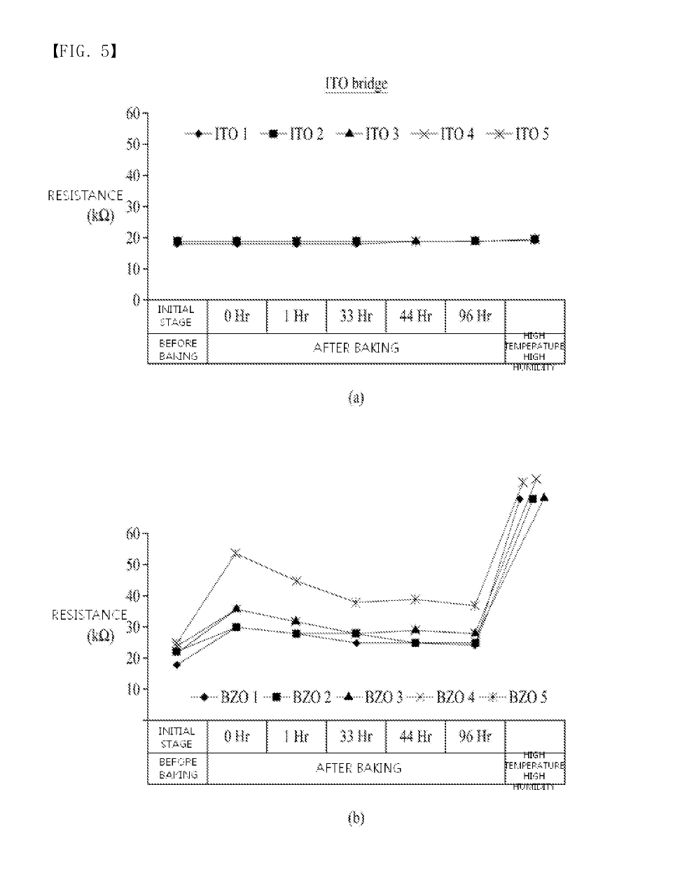

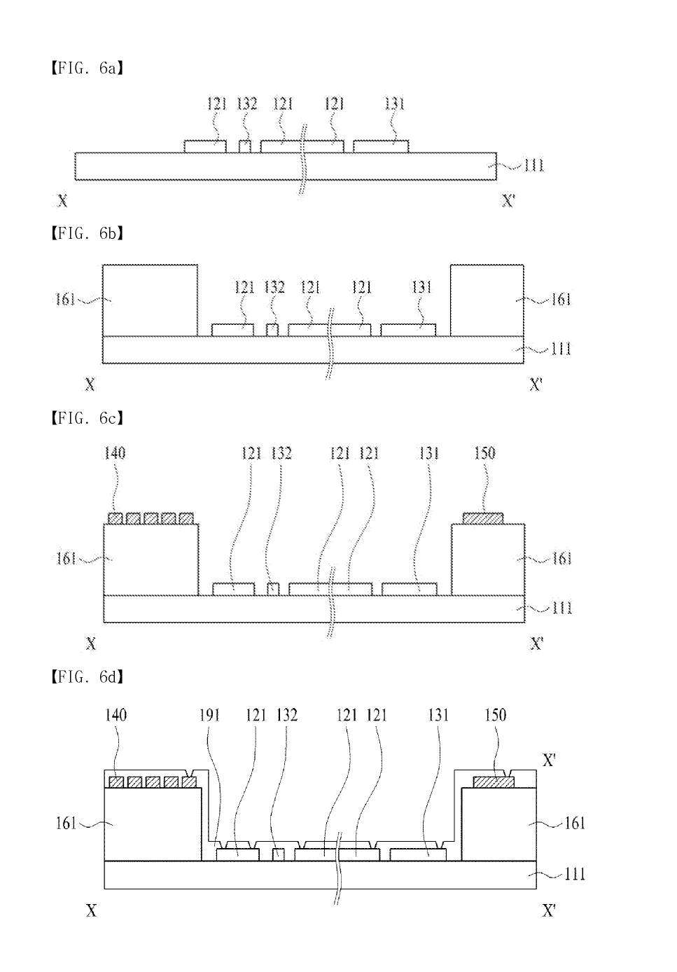

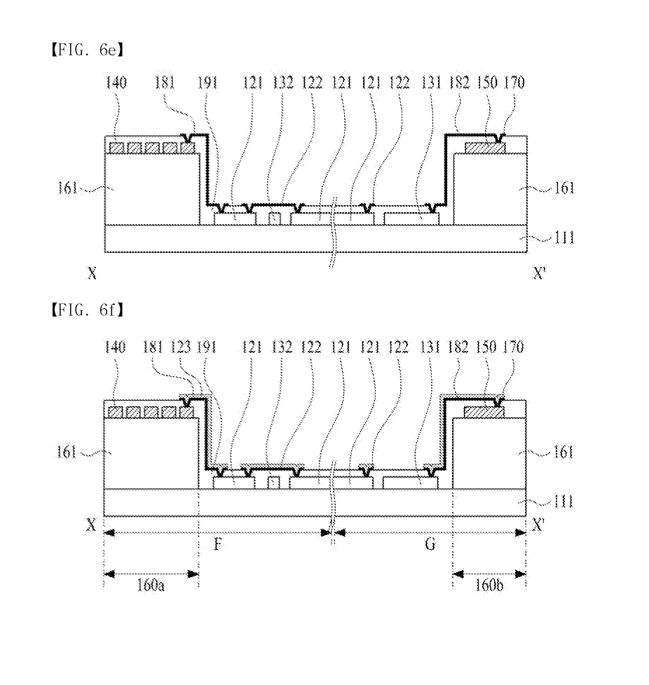

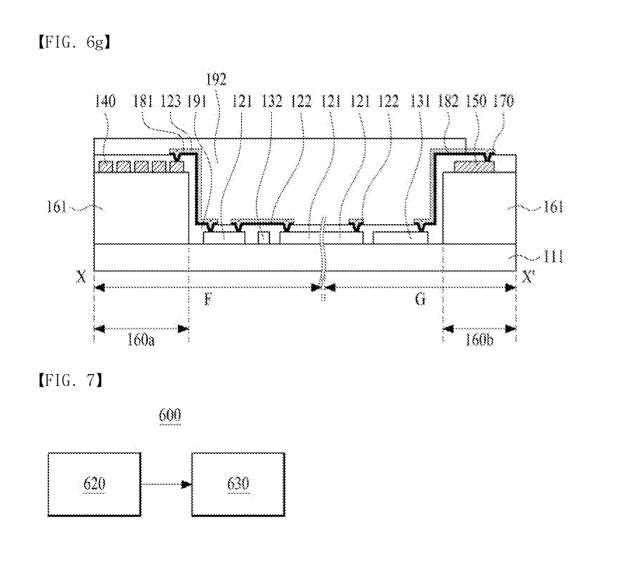

Hereinafter, a method of manufacturing the touch panel 100 will be described in detail with reference to FIGS. 6A to 6G and 7 to 9.

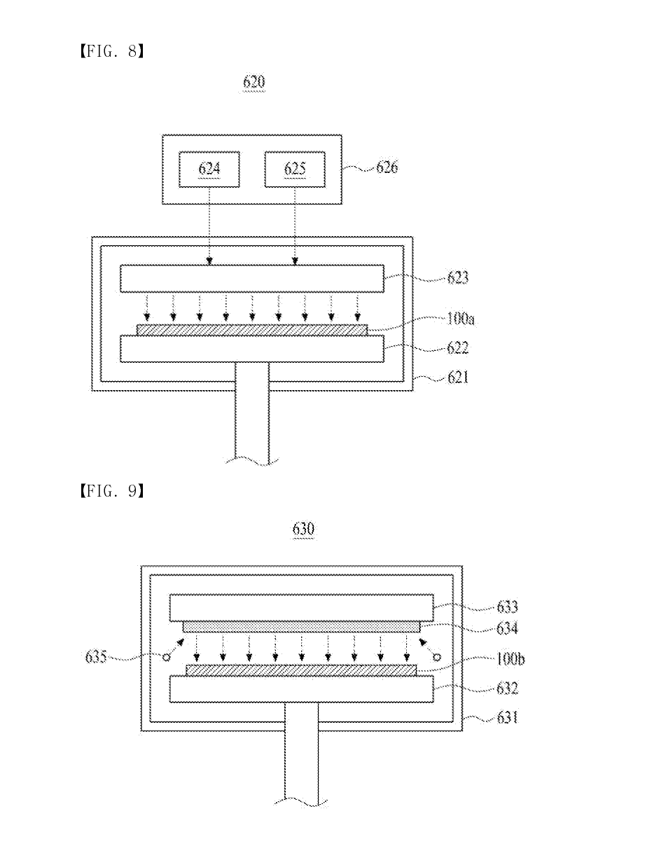

FIGS. 6A to 6G are exemplary diagrams sequentially illustrating a touch panel manufacturing method according to an embodiment of the present invention. FIG. 7 is an exemplary diagram illustrating a configuration of a touch pane manufacturing system according to an embodiment of the present invention. FIG. 8 is an exemplary diagram illustrating a first touch panel manufacturing apparatus of FIG. 7. FIG. 9 is an exemplary diagram illustrating a second touch panel manufacturing apparatus of FIG. 7.

A touch panel manufacturing method to be described below will be described as an example of a touch panel manufacturing method according to an embodiment of the present invention. Therefore, the touch panel manufacturing method according to an embodiment of the present invention may be variously changed depending on a structure of a touch panel.

First, referring to FIG. 6A, the receiving electrode parts 121, the driving electrode parts 131, and the driving electrode connection parts 132 are disposed on a substrate 111.

A thickness of each of the receiving electrode parts 121, the driving electrode parts 131, and the driving electrode connection parts 132 is about 300 nm.

The substrate 111 may be a transparent glass substrate, a transparent plastic substrate, or a transparent synthetic resin film.

The plastic substrate or the synthetic resin film may be formed of at least one selected from polyimide (PI), polycarbonate (PC), polynorborneen (PNB), polyethyleneterephthalate (PET), polyethylenapthanate (PEN), and polyethersulfone (PES).

The receiving electrode parts 121, the driving electrode parts 131, and the driving electrode connection parts 132 may be formed of ITO.

In this case, ITO may be formed on the substrate 111 by the PVD process.

Examples of the PVD process include a sputtering process, an E-beam evaporation process, a thermal evaporation process, a laser molecular beam epitaxy (L-MBE) process, and a pulsed laser deposition (PLD) process. In particular, the receiving electrode parts 121, the driving electrode parts 131, and the driving electrode connection parts 132 may be formed on the substrate 111 by the sputtering process.

Moreover, the receiving electrode parts 121, the driving electrode parts 131, and the driving electrode connection parts 132 may be formed of transparent first oxide having conductivity, for example, Zn-based oxide such as ZnO. In this case, the receiving electrode parts 121, the driving electrode parts 131, and the driving electrode connection parts 132 may be formed through deposition by the MOCVD process.

In particular, when the receiving electrode parts 121, the driving electrode parts 131, and the driving electrode connection parts 132 are formed of the first oxide, second oxide such as ITO or Al₂O₃ is formed on the first oxide. In this case, the second oxide protects the first oxide from a high temperature and high humidity.

A process of forming the first oxide in the MOCVD process will be described in detail in a process of forming the bridges 181, 182 and 122.

Next, referring to FIG. 6B, the light blocking layer 161 is formed in the non-display area 160. A thickness of the light blocking layer 161 is about 20 μm or more. A thickness of the light blocking layer 161 is formed 70 or more times thicker than that of each of the receiving electrode parts 121, the driving electrode parts 131, and the driving electrode connection parts 132.

Next, referring to FIG. 6C, the receiving electrode lines 140 and the driving electrode lines 150 are formed on the light blocking layer 161.

For example, five the receiving electrode lines 140 are formed in the first non-display area 160a. The receiving electrode lines 140 extend to the second non-display area 160b, and four the driving electrode lines 150 are formed in the second non-display area 160b.

Since the receiving electrode lines 140 and the driving electrode lines 150 are formed on the light blocking layer 161 formed in the non-display area 160 through which light cannot pass, the receiving electrode lines 140 and the driving electrode lines 150 may not be formed of a transparent material such as ITO or ZnO. Therefore, the receiving electrode lines 140 and the driving electrode lines 150 may be formed of various kinds of opaque metal materials having good conductivity.

Next, referring to FIG. 6D, an insulating layer 191 is coated on the receiving electrode parts 121, the driving electrode parts 131, the driving electrode connection parts 132, the receiving electrode lines 140, and the driving electrode lines 150. The insulating layer 191 may be formed of an insulating material such as PAC or PAS.

A plurality of contact holes are formed in the insulating layer 191 by using a mask.

For example, in the insulating layer 191, two contact holes are formed at positions respectively corresponding to the receiving electrode parts 121, one contact hole is formed at a position corresponding to each of the receiving electrode lines 140 and the driving electrode lines 150, and one contact hole is formed at a position corresponding to each of the driving electrode parts 131 adjacent to the light blocking layer 161 among the driving electrode parts 131. The contact holes may be formed by a photomask process.

Next, referring to FIG. 6E, the receiving electrode bridge 122 that connects through the contact holes two the receiving electrode parts 121 which are separated from each other, the receiving line bridge 181 that connects the receiving electrode line 140 to the receiving electrode part 121 through the contact holes, and the driving line bridge 182 that connects the driving electrode line 150 to the driving electrode part 131 through the contact holes are disposed on the insulating layer 191.

A process of forming the receiving electrode bridge 122, the receiving line bridge 181, and the driving line bridge 182 is performed a first touch panel manufacturing apparatus 620 illustrated in FIGS. 7 and 8.

The first touch panel manufacturing apparatus 620 is used to form the bridges 181, 182 and 122 which are formed in a fine pattern, and uses a chemical vapor deposition (CVD) process using a metal organic precursor. That is, the first touch panel manufacturing apparatus 620 forms the bridges by depositing transparent the first oxide (for example, Zn-based oxide such as ZnO or BZO) having conductivity in the CVD process. Hereinafter, for convenience of a description, a case in which transparent the first oxide having conductivity is ZnO will be described as an example of the present invention. In this case, the electrode parts 121 and 131 may be formed of ZnO.

In order to form the bridges, as illustrated in FIG. 8, the first touch panel manufacturing apparatus 620 includes a chamber 621, a substrate supporting unit 622, and a plurality of gas jetting devices 626 and 623. The gas jetting devices 626 and 623 include a gas jetting unit 623 and a gas supply unit 626. The gas supply unit 626 includes a first gas supplier 624 and a second gas supplier 625.

However, the first touch panel manufacturing apparatus 620 may be configured in various types in addition to a type illustrated in FIG. 8.

When the insulating layer 191 is formed on the substrate 111 by performing the above-described processes of FIGS. 6A to 6D, the substrate 100a is transferred to inside the chamber 621 of the first touch panel manufacturing apparatus 620 illustrated in FIG. 8, and is disposed on the substrate supporting unit 622.

Subsequently, a metal source material (a Zn-based metal precursor) and a reaction gas are jetted onto the substrate 100a through the gas jetting unit 623, and thus, the bridges 181, 182 and 122 are formed.

Next, referring to FIG. 6F, the second oxide 123 for protecting the first oxide from a high temperature and high humidity is formed on the bridges 181, 182 and 122 formed of the first oxide.

A process of forming the second oxide 123 is performed by a second touch panel manufacturing apparatus 630 illustrated in FIGS. 7 and 9.

The second touch panel manufacturing apparatus 630 forms the second oxide, which protects the bridges 181, 182 and 122 from a high temperature and high humidity, on the bridges 181, 182 and 122 by using the PVD process.

In order to form the second oxide, as illustrated in FIG. 9, the second touch panel manufacturing apparatus 630 includes a chamber 631, a susceptor 632, and a target supporting part 633.

However, the second touch panel manufacturing apparatus 630 may be configured in various types in addition to a type illustrated in FIG. 9.

When the bridges 181, 182 and 122 formed of the first oxide are formed on the substrate 100b by performing the above-described processes of FIG. 6E, the substrate 100b is transferred to inside the chamber 631 of the second touch panel manufacturing apparatus 630 illustrated in FIG. 9, and is disposed on the susceptor 632.

Subsequently, the second touch panel manufacturing apparatus 630 collides ions 635 of discharged inert gases with a second oxide target 634 equipped in the target supporting part 633, and deposits atoms, separated from the second oxide target 634, on the first oxides 181, 182 and 122, thereby forming the second oxide 123 on the first oxides 181, 182 and 122.

Finally, referring to FIG. 6G, the protective layer 192 is formed all over the substrate including the second oxide 123. In this case, the protective layer 192 is formed in order for an end of the driving line bridge 182 to be exposed to the outside. A portion, which is exposed to the outside without being covered by the protective layer 192, becomes the pad 170. The FPCB 200 equipped with the touch driver IC 300 is electrically connected to the pad 170.

A process of manufacturing the touch panel 100 is finished through the processes.

The touch panel 100 connected to the FPCB 200 is attached to an upper end of the panel by an adhesive such as an optically clear resin (OCR) or an adhesive tape such as an optically clear adhesive (OCA), and thus, a display device including the touch panel 100 is manufactured.

The above-described touch panel manufacturing method according to an embodiment of the present invention will be briefly summarized.

The touch panel manufacturing method according to an embodiment of the present invention includes an operation of forming the electrode parts 121 and 131 in the display area 110 of the substrate, an operation of forming the light blocking layer 161 in the non-displays 160a and 160b of the substrate, an operation of forming the electrode lines 140 and 150 on the light blocking layer 161, an operation of forming the line bridges 181 and 182, which connect the electrode parts 121 and 131 to the electrode lines, by using transparent the first oxide having conductivity, and an operation of forming the second oxide 123, which protect the first oxide, on the first oxides 181 and 182.

Here the second oxide has characteristic which is more robust than the first oxide to a high temperature and high humidity.

For example, each of the first oxides 181 and 182 is ZnO or BZO in which boron is doped on ZnO, and the second oxide 123 may be ITO or Al₂O₃.

Moreover, in the touch panel manufacturing method according to an embodiment of the present invention, the line bridges 181 and 182 are formed by the MOCVD process.

Moreover, in the touch panel manufacturing method according to an embodiment of the present invention, the operation of forming the second oxide on the first oxide is performed by the PVD process.

Moreover, the electrode parts 121 and 131 include the first electrode parts, which configure the first touch electrode and are electrically disconnected from each other, and the second electrode parts which configure the second touch electrode and are electrically connected to each other. In the touch panel manufacturing method according to an embodiment of the present invention, the electrode bridges 122 which electrically connect the first electrode parts may be formed of the same material as that of the line bridges 181 and 182 by using the same process as that of the line bridges 181 and 182.

Moreover, in the present embodiment, the electrode parts 121 and 131 may be formed of the first oxide which has conductivity and is transparent. In this case, the second oxide 123 may be deposited on the electrode parts 121 and 131 formed of the first oxide.

Hereinafter, a touch panel manufacturing system 600 according to an embodiment of the present invention will be described in detail. In the following description, the above-described details will be briefly described or are omitted.

The touch panel manufacturing system 600 according to an embodiment of the present invention, as illustrated in FIG. 7, includes the first touch panel manufacturing apparatus 620 and the second touch panel manufacturing apparatus 630.

First, as illustrated in FIG. 8, the first touch panel manufacturing apparatus 620 includes: the chamber 621 that has a reaction space; the substrate supporting unit 622 that supports a manufacturing substrate 100a which includes a plurality of electrode parts formed in a display area, a light blocking layer formed in a non-display area which is formed outside the display area, and an electrode line formed on the light blocking layer, and is disposed in the chamber 621; and the gas jetting device 623 that jets a metal source material and a reaction gas onto the manufacturing substrate 100a so as to form transparent first oxide (ZnO or BZO) having conductivity, which is used to form a line bridge which connects the electrode part to the electrode line, on the manufacturing substrate 100a. In this case, the manufacturing substrate 100a denotes a substrate which has undergone the processes of FIGS. 6A to 6D.

The above-described processes of FIGS. 6A to 6D may be respectively performed by a sputtering apparatus for depositing ITO, an apparatus for forming the insulating layer 191, and an apparatus for forming the contact holes in the insulating layer 191. The apparatuses are apparatuses which are generally used to manufacture the touch panel 100, and thus, their detailed descriptions are not provided.

The gas jetting device includes the gas jetting unit 623 and the gas supply unit 626. The gas supply unit 626 includes the first gas supplier 624 and the second gas supplier 625.

The gas supply unit 626 of the gas jetting device may jet a Zn-based metal precursor as the metal source material, and jet an oxygen-containing gas as the reaction gas. To this end, the first gas supplier 624 may supply the metal source material to the gas jetting unit 623, and the second gas supplier 625 may supply the reaction gas to the gas jetting unit 623.

Moreover, the gas jetting device jets the metal source material and the reaction gas onto the manufacturing substrate 100a so as to form the electrode bridges 122, which electrically connect the second electrode parts, along with the line bridges 181 and 182.

The first touch panel manufacturing apparatus 620 forms the line bridge 122 on the manufacturing substrate 100a by using the MOCVD process. Therefore, the first touch panel manufacturing apparatus 620 fundamentally includes elements included in apparatuses which perform the MOCVD process.

Second, as illustrated in FIG. 9, the second touch panel manufacturing apparatus 630 includes: a chamber 631 that has a reaction space; a susceptor 632 that is disposed in the chamber 631, is supplied with power having a first polarity, and supports a manufacturing substrate 100b which includes a plurality of electrode parts which are formed in a display area, a light blocking layer formed in a non-display area which is formed outside the display area, an electrode line formed on the light blocking layer, and a line bridge which is formed of transparent first oxide having conductivity by the MOCVD process and connects the electrode part to the electrode line; and a target supporting part 633 that is equipped with a second oxide target 634, and is supplied with power having a second polarity.

The second touch panel manufacturing apparatus 630 collides ions 635 of discharged inert gases with the second oxide target 634, and deposits atoms, separated from the second oxide target 634, on the first oxide formed on the manufacturing substrate 110b, thereby forming the second oxide on the first oxide.

In this case, the manufacturing substrate 100b denotes a substrate which has undergone the first touch panel manufacturing apparatus 620. Therefore, the line bridge 122 is formed on the manufacturing substrate 100b loaded into the second touch panel manufacturing apparatus 620.

The second touch panel manufacturing apparatus 630 glow-discharges an inert gas (for example, Ar, Kr, Xe, or the like), which flows into the chamber 631, to generate a positive ion 635, and then collides the positive ion 635 with the second oxide target 634 to which a second polarity (for example, a negative (−) polarity) is supplied.

An atom, which is emitted from the second oxide target 634 by the collision operation, moves toward the susceptor 632 to which the first polarity (for example, a positive (+) polarity) is supplied, and is deposited on the manufacturing substrate 100b.

That is, the second touch panel manufacturing apparatus 630 forms the second oxide 123 on the first oxides 181 and 182, which is formed on the manufacturing substrate 100b, by using the PVD process.

Therefore, the second touch panel manufacturing apparatus 630 fundamentally includes elements included in apparatuses which perform the PVD process.

The above-described details will be summarized below.

The present invention relates to the manufacturing of a touch panel, and particularly, the bridges 122, 181 and 182 are formed of the first oxide (for example, Zn-based oxide such as ZnO or BZO), and the second oxide which is robust to a high temperature and high humidity is formed on the first oxide so as to protect the first oxide which is vulnerable to a high temperature and high humidity.

According to the embodiments of the present invention, the bridge configuring the receiving electrodes and driving electrodes of the touch panel may be formed of Zn-based oxide (first oxide) such as ZnO or BZO instead of ITO, and the receiving electrodes and the driving electrodes may be formed of the first oxide. Particularly, since the first oxide is manufactured by the first touch panel manufacturing apparatus 620 using the MOCVD process, a step coverage of the bridge is improved, and thus, a productivity of the touch panel is improved. Also, the manufacturing cost of the touch panel is reduced by using ZnO or BZO cheaper than ITO. According to a simulation result and an experiment result of a touch panel manufactured according to the present invention, when the bridge (particularly, the line bridges 181 and 182 contacts the light blocking layer 161, a step coverage is improved, and thus, a productivity of 90% or more is secured.

Moreover, according to the embodiments of the present invention, since the second oxide robust to a high temperature and high humidity is formed on the first oxide vulnerable to a high temperature and high humidity, a characteristic of the first oxide cannot be changed under a high temperature and high humidity. Therefore, a performance of a touch panel manufactured by the first oxide can be enhanced.

Moreover, in a related art touch panel manufacturing method using ITO, when an error occurs, it is impossible to perform a re-work process. However, according to the embodiments of the present invention, the re-work process is easily performed by using Zn-based oxide, and thus, productivity is improved.

Hereinabove, it has been described that one the second oxide is formed on the first oxide used as the bridge. However, the second oxide may be formed in a multi-layer structure for protecting the first oxide from a high temperature and high humidity. That is, according to the embodiments of the present invention, each of the elements used as the electrodes of the touch panel may be fundamentally formed of the first oxide (for example, ZnO or BZO), and the second oxide for protecting the first oxide from a high temperature and high humidity may be formed of multilayers by using ITO or another material (for example, Al₂O₃).

Due to the multi-layer structure, the touch panel may use a good characteristic of the first oxide, for example, a characteristic in which a step coverage is good, and can prevent a characteristic of the first oxide from being deformed by a high temperature and high humidity.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A method of manufacturing a touch panel, the method comprising:
forming a plurality of electrode parts in a display area of a substrate;
forming a light blocking layer in a non-display area of the substrate;
forming an electrode line on the light blocking layer;
forming a first oxide layer by using first oxide, for forming a line bridge which connects the electrode part to the electrode line; and
forming a second oxide layer on the first oxide layer by using second oxide which has a lower step coverage than a step coverage of the first oxide and has a lower resistance than a resistance of the first oxide, for protecting the first oxide.

2. The method of claim 1, wherein the forming of the line bridge uses a metal organic chemical vapor deposition (MOCVD) process.

3. The method of claim 1, wherein the second oxide is more robust than the first oxide to a high temperature and high humidity.

4. The method of claim 1, wherein,
the first oxide is zinc oxide (ZnO) or boron zinc oxide (BZO) in which boron is doped on ZnO, and
the second oxide is oxide containing indium.

5. The method of claim 1, wherein,
the first oxide is zinc oxide (ZnO) or boron zinc oxide (BZO) in which boron is doped on ZnO, and
the second oxide is oxide containing tin.

6. The method of claim 1, wherein,
the plurality of electrode parts comprise a plurality of first electrode parts, which configure a first touch electrode and are electrically disconnected from each other, and a plurality of second electrode parts which are electrically connected to each other to configure a second touch electrode, and
the forming of the line bridge comprises forming a plurality of electrode bridges, which electrically connect the plurality of first electrode parts, by using the same material as a material of the line bridge and the same process as a process of forming the line bridge.

7. The method of claim 1, wherein the plurality of electrode parts are formed of the first oxide.

8. The method of claim 7, further comprising depositing the second oxide on the plurality of electrode parts formed of the first oxide.

9. A touch panel manufacturing apparatus comprising:
a chamber that includes a reaction space;
a susceptor that is disposed in the chamber, is supplied with power having a first polarity, and supports a manufacturing substrate which includes a plurality of electrode parts which are formed in a display area, a light blocking layer formed in a non-display area which is formed outside the display area, an electrode line formed on the light blocking layer, and a line bridge which is formed of first oxide by a metal organic chemical vapor deposition (MOCVD) process and connects the electrode part to the electrode line; and
a target supporting part that is equipped with a second oxide target, and is supplied with power having a second polarity,
wherein the touch panel manufacturing apparatus collides ions of discharged inert gases with the second oxide target and deposits atoms, separated from the second oxide target, on the first oxide to form second oxide on the first oxide.

10. The touch panel manufacturing apparatus of claim 9, wherein,
the first oxide is zinc oxide (ZnO) or boron zinc oxide (BZO) in which boron is doped on ZnO, and
the second oxide is oxide containing indium, which is more robust than the first oxide to a high temperature and high humidity, or oxide containing tin.

11. The touch panel manufacturing apparatus of claim 9, wherein the second oxide is deposited on the first oxide by a physical vapor deposition (PVD) process.

12. A touch panel manufacturing system comprising:
a first touch panel manufacturing apparatus that jets a metal source material and a reaction gas onto a manufacturing substrate for forming first oxide, which is used as a line bridge connecting an electrode part to an electrode line, on the manufacturing substrate, wherein the manufacturing substrate includes the plurality of electrode parts formed in a display area, a light blocking layer formed in a non-display area which is formed outside the display area, and the electrode line formed on the light blocking layer; and
a second touch panel manufacturing apparatus that forms second oxide, which is more robust than the first oxide to a high temperature and high humidity, on the first oxide of the manufacturing substrate unloaded from the first touch panel manufacturing apparatus.

13. The touch panel manufacturing system of claim 12, wherein,
the first oxide is zinc oxide (ZnO) or boron zinc oxide (BZO) in which boron is doped on ZnO, and
the second oxide is oxide containing indium or oxide containing tin.

14. The touch panel manufacturing system of claim 12, wherein,
the first touch panel manufacturing apparatus forms the line bridge by using a metal organic chemical vapor deposition (MOCVD) process, and
the second touch panel manufacturing apparatus forms the second oxide on the first oxide by using a physical vapor deposition (PVD) process.

15. A method of manufacturing a touch panel, the method comprising:
forming a plurality of electrode parts in a display area of a substrate;
forming a light blocking layer in a non-display area of the substrate;
forming an electrode line on the light blocking layer;
forming a step coverage increase layer for forming a line bridge which connects the electrode part to the electrode line; and
forming a resistance decrease layer on the step coverage increase layer.
